(19) United States
(12) Patent Application Publication
(10) Pub. No.: US 2025/0044488 A1
(43) Pub. Date: Feb. 6, 2025

(54) DISPLAY APPARATUS WITH IMPROVED REFLECTIVE VISIBILITY

(71) Applicant: LG Display Co., Ltd., Seoul (KR)

(72) Inventors: JuHun MIN, Paju-si (KR); SunWoong KIM, Paju-si (KR); SeungSoo YANG, Paju-si (KR); DongUk KIM, Paju-si (KR)

(73) Assignee: LG Display Co., Ltd., Seoul (KR)

(21) Appl. No.: 18/790,851

(22) Filed: Jul. 31, 2024

(30) Foreign Application Priority Data
Jul. 31, 2023 (KR) 10-2023-0100108

(51) Int. Cl. G02B 5/02; H10K 59/80

(52) U.S. Cl. CPC G02B 5/0242; G02B 5/0278; H10K 59/8791

(57) ABSTRACT

A display apparatus and a coherence prevention member are discussed. The display apparatus in one example includes a display panel configured to display an image, and a coherence prevention layer on the display panel. The coherence prevention layer includes a refractive index particle layer and a filling layer on the refractive index particle layer. The refractive index particle layer includes a light-transmissive matrix and refractive index particles dispersed in the light-transmissive matrix. Further, the filling layer and the refractive index particles have different refractive indices.

### CROSS-REFERENCE TO RELATED APPLICATIONS

This application claims priority to Korean Patent Application No. 10-2023-0100108 filed in the Republic of Korea on Jul. 31, 2023, the entire contents of which is hereby expressly incorporated by reference into the present application.

### BACKGROUND

### Field

The present disclosure relates to a display apparatus capable of minimizing the occurrence of spectral dispersion patterns caused by destructive interference or constructive interference of reflected light during external light is reflected.

### Discussion of the Related Art

Recently, flat display apparatus or flexible display apparatus have been used as a display apparatus. Among the display apparatuses, an organic light emitting display apparatus, which is a self-emitting display apparatus, has the advantages of a wide viewing angle, excellent contrast, and fast response speed. In addition, the organic light emitting display apparatus can be easily applied to a flexible display apparatus.

When the display apparatus is used in an environment with external light, contrast or visibility can be reduced and black visibility can be reduced.

For example, pixels, electrodes, or color filters can be regularly arranged in a display panel of a display apparatus, and apertures can be regularly arranged between these regularly arranged components. These regularly arranged apertures can serve as slits that generate diffraction of light. As a result, coherence due to diffraction can occur in the process of external light being reflected from the display panel, and the coherence can cause occurrences of a diffraction pattern, reflection diffraction mura, rainbow mura, rainbow speckle pattern or circular ring patterns, or the like.

In order to prevent reflection of external light or deterioration of visibility due to external light reflection, polarizers have conventionally been attached to the front surface of the display apparatus. The polarizer prevents external light from being reflected to the outside after entering the display apparatus and reduces the luminance of the reflected external light, thereby prevents a decrease in visibility due to external light. However, the polarizer is a film type and has a structure in which several layers, for example, a linear polarizing film, a retardation film, a support film, or the like are stacked, so the polarize can have the disadvantage of being expensive and thick.

### SUMMARY OF THE DISCLOSURE

The present disclosure has been made in view of the above-mentioned and other issues associated with the related art and it is an object of the present disclosure to provide a display apparatus capable of effectively improving diffraction interference patterns generated by reflection of external light. An embodiment of the present disclosure provides a display apparatus capable of preventing reflection of external light or visibility deterioration due to external light reflection without using a polarizer.

It is another object of the present disclosure to provide a display apparatus and an optical member capable of suppressing or weakening the coherence of reflected light in order to prevent occurrence of diffraction interference patterns due to external light reflection. The optical member according to an embodiment of the present disclosure includes materials with different refractive indices, and these materials can change the propagation speed of external light and reflected light, thereby weakening the coherence of reflected light.

It is still another object of the present disclosure to provide a display apparatus comprising a coherence prevention layer capable of weakening the coherence of reflected light, in which the coherence prevention layer suppresses or weakens the coherence of reflected light, thereby suppressing the occurrence of diffraction interference patterns due to reflection of external light.

In accordance with an aspect of the present disclosure, the above and other objects can be accomplished by the provision of display apparatus comprising a display panel for displaying an image and a coherence prevention layer on the display panel, wherein the coherence prevention layer comprises a refractive index particle layer and a filling layer on the refractive index particle layer, wherein the refractive index particle layer comprises a light-transmissive matrix and refractive index particles dispersed in the light-transmissive matrix, wherein the filling layer and the refractive index particles have different refractive indices.

According to aspects of the present disclosure, the refractive index particles can include a first particle and a second particle, wherein the first particle has a first refractive index and the second particle has a second refractive index, and the first refractive index is different from the second refractive index.

According to aspects of the present disclosure, a difference in refractive index between the refractive index particles and the filling layer can be in a range of 0.05 to 0.40.

According to aspects of the present disclosure, the first particle and the second particle can have a refractive index difference in a range of 0.05 to 0.40.

According to aspects of the present disclosure, the first particle and the second particle can have different particle diameters.

According to aspects of the present disclosure, the refractive index particles can have an average particle diameter of 760 nm to 20 μm.

According to aspects of the present disclosure, the refractive index particles can further comprise a third particle having a refractive index different from the first refractive index of the first particle and the second refractive index of the second particle.

According to aspects of the present disclosure, the refractive index particles can comprise at least one selected from the group consisting of polymethylmethacrylate (PMMA), polycarbonate (PC), polyethylene terephthalate (PET), polyurethane (PU), polystyrene (PS), nylon, silicon oxide (SiO2), titanium oxide (TiO2), silicon nitride (SixNy), silicon oxide nitride (SiON), aluminum oxide (AlOx), aluminum nitride (AlON), zinc oxide (ZnO), tantalum oxide (Ta2O5), magnesium fluoride (MgF2), yttrium oxide (Y2O3), and hafnium oxide (HfO2).

According to aspects of the present disclosure, the refractive index particle layer can have a plurality of lens patterns.

According to aspects of the present disclosure, the refractive index particle layer can have a monolayer structure by the refractive index particles.

According to aspects of the present disclosure, the refractive index particle layer can have a packing density of 90% or more in a plan view, wherein the packing density is calculated as a ratio of the area of the refractive index particles to the area of the refractive index particle layer, in a plan view.

According to aspects of the present disclosure, the display panel can include a color filter layer, wherein the coherence prevention layer is disposed on the color filter layer.

Another embodiment of the present disclosure provides a coherence prevention member including a refractive index particle layer and a filling layer on the refractive index particle layer, wherein the refractive index particle layer comprises a light-transmissive matrix and refractive index particles dispersed in the light-transmissive matrix, wherein the refractive index particles and the filling layer have different refractive indices.

According to aspects of the present disclosure, the refractive index particles can include a first particle and a second particle, wherein the first particle has a first refractive index and the second particle has a second refractive index, and the first refractive index is different from the second refractive index.

According to aspects of the present disclosure, the first particle and the second particle can have different particle diameters.

According to aspects of the present disclosure, the refractive index particles can have an average particle diameter of 760 nm to 20 μm.

According to aspects of the present disclosure, a difference in refractive index between the refractive index particles and the filling layer can be in a range of 0.05 to 0.40.

According to aspects of the present disclosure, the first particle and the second particle can have a refractive index difference in the range of 0.05 to 0.40.

According to aspects of the present disclosure, the refractive index particles can further comprise a third particle having a refractive index different from the first refractive index of the first particle and the second refractive index of the second particle.

According to aspects of the present disclosure, the refractive index particles can include at least one selected from the group consisting of polymethylmethacrylate (PMMA), polycarbonate (PC), polyethylene terephthalate (PET), polyurethane (PU), polystyrene (PS), nylon, silicon oxide (SiO2), titanium oxide (TiO2), silicon nitride (SixNy), silicon oxide nitride (SiON), aluminum oxide (AlOx), aluminum nitride (AlON), zinc oxide (ZnO), tantalum oxide (Ta2O5), magnesium fluoride (MgF2), yttrium oxide (Y2O3), and hafnium oxide (HfO2).

According to aspects of the present disclosure, the refractive index particle layer can have a plurality of lens patterns.

According to aspects of the present disclosure, the refractive index particle layer can have a monolayer structure by the refractive index particles.

According to aspects of the present disclosure, the refractive index particle layer can have a packing density of 90% or more in a plan view, wherein the packing density is calculated as a ratio of the area of the refractive index particles to the area of the refractive index particle layer, in a plan view.

Another embodiment of the present disclosure provides a display apparatus including a display panel and the coherence prevention member described above.

According to aspects of the present disclosure, the display apparatus may not include a polarizer.

According to an embodiment of the present disclosure, a coherence prevention layer is placed in a display apparatus to weaken the incoherence of the reflected light, thereby preventing diffraction interference patterns from being created by the reflection of external light. The propagation speed of external light can be changed by the coherence prevention layer, thus which can suppress or weaken the coherence of reflected light. As a result, the generation of diffraction interference patterns due to external light reflection can be suppressed. In addition, the display apparatus according to an embodiment of the present disclosure need not include a polarizer, and a coherence prevention layer is disposed on the display panel so that diffraction interference patterns generated on the display surface of the display apparatus by the reflection of external light can be suppressed or prevented.

In addition, in the display apparatus according to an embodiment of the present disclosure, black deterioration due to reflection of external light can be reduced or black visibility, a degree of black when a display surface is viewed in a front direction, can be improved, and the occurrence of rainbow mura and circular ring mura can be minimized or reduced, thereby a real black can be realized in a non-driven or off state.

In addition to the above-mentioned effects, other features and advantages of the present disclosure are described below, or can be clearly understood by those skilled in the art from the description.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features and other advantages of the present disclosure will be more clearly understood from the following detailed description taken in conjunction with the accompanying drawings, in which:

FIG. 1 is a schematic diagram of a display apparatus according to an embodiment of the present disclosure.

FIG. 2 is a schematic diagram of an embodiment of a display panel.

FIG. 3 is a plan view showing a planar structure of a pixel P shown in FIG. 2.

FIG. 4 is a cross-sectional view showing a cross-sectional structure of one subpixel according to an embodiment of the present disclosure.

FIG. 5A is a schematic diagram illustrating a coherence of reflected light generated in a display apparatus according to a reference example and a mechanism of generating diffraction patterns.

FIG. 5B is a picture illustrating diffraction patterns caused by an external light source in a display apparatus according to a reference example.

FIG. 6 is a schematic diagram illustrating a mechanism by which a coherence and diffraction patterns occur by light passing through a slit or an aperture.

FIG. 7 is a partial enlarged view of the coherence prevention layer shown in FIG. 4.

FIG. 8 is a schematic diagram illustrating a path difference of light passing through the coherence prevention layer.

FIG. 9 is a schematic diagram illustrating a mechanism of diffraction interference pattern cancellation or suppression.

FIG. 10A is a schematic diagram illustrating a mechanism by which coherence of reflected light is suppressed in a display apparatus according to an embodiment of the present disclosure.

FIG. 10B is a picture showing that the diffraction pattern caused by an external light source is reduced in a display apparatus according to an embodiment of the present disclosure.

FIG. 11A is a partial plan view of a refractive index particle layer.

FIG. 11B is a schematic diagram illustrating a structure in which particles are dispersed and stacked in a matrix.

FIGS. 12A and 12B are pictures diffraction patterns caused by an external light on display apparatuses according to comparative examples.

FIGS. 12C and 12D are pictures of display apparatuses illuminated by an external light source, according to an embodiment of the present disclosure.

FIG. 13 is a schematic cross-sectional view of a coherence prevention member according to another embodiment of the present disclosure.

FIG. 14 is a schematic cross-sectional view of a display apparatus according to another embodiment of the present disclosure.

FIG. 15 is a schematic cross-sectional view of a display apparatus according to another embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully explain the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout the disclosure. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part can be added unless ‘only’ is used. The terms of a singular form can include plural forms unless referred to the contrary.

In construing an element, the element is construed as including an error range although there is no explicit description.

In describing a position relationship, for example, when the position relationship is described as ‘upon’, ‘above’, ‘below’, and ‘next to’, one or more portions can be arranged between two other portions unless ‘just’ or ‘direct’ is used.

Spatially relative terms such as “below”, “beneath”, “lower”, “above”, and “upper” can be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below”, or “beneath” another device can be arranged “above” another device. Therefore, an exemplary term “below or beneath” can include “below or beneath” and “above” orientations. Likewise, an exemplary term “above” or “on” can include “above” and “below or beneath” orientations.

In describing a temporal relationship, for example, when the temporal order is described as “after,” “subsequent,” “next,” and “before,” a case which is not continuous can be included, unless “just” or “direct” is used.

It will be understood that, although the terms “first”, “second”, etc. can be used herein to describe various elements, these elements should not be limited by these terms. These terms are only used to partition one element from another. For example, a first element could be termed a second element, and, similarly, a second element could be termed a first element, without departing from the scope of the present invention.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship. Further, the term “can” encompasses all the meanings and coverages of the term “may”.

In the drawings, the same or similar elements are denoted by the same reference numerals even though they are depicted in different drawings.

Hereinafter, examples or embodiments of the present disclosure will be described with reference to the attached drawings. The scale of the components shown in the drawings can be different from the actual scale for convenience of description, and is therefore not limited to the scale shown in the drawings. Further, all the components of each display apparatus or device according to all embodiments of the present disclosure are operatively coupled and configured.

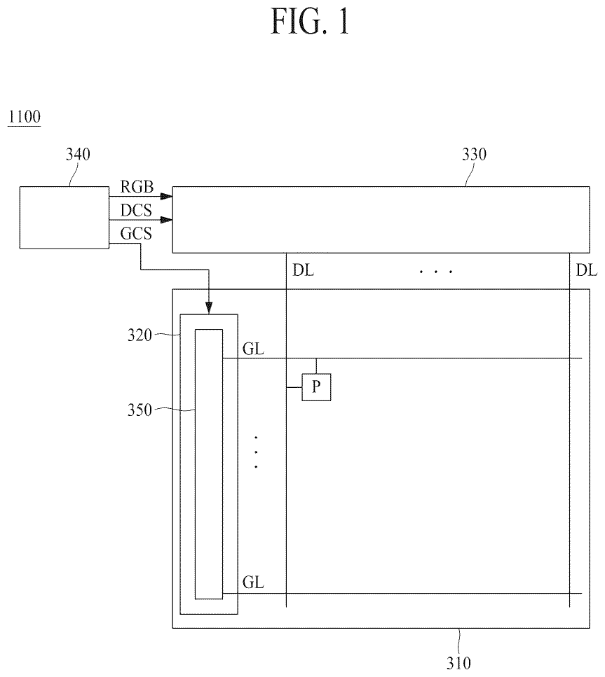

FIG. 1 is a schematic diagram of a display apparatus 1100 according to an embodiment of the present disclosure.

Referring to FIG. 1, the display apparatus 1100 according to an embodiment of the present disclosure includes a display panel 310, a gate driver 320, a data driver 330, and a controller 340.

Gate lines GL and data lines DL are placed in the display panel 310, and pixels P are disposed at intersections of the gate lines GL and data lines DL. Images are displayed by driving pixels P.

The controller 340 controls the gate driver 320 and data driver 330.

The controller 340 uses a signal supplied from an external system to generate a gate control signal GCS to control the gate driver 320 and a data control signal DCS to control the data driver 330. In addition, the controller 340 samples input image data input from an external system, realigns it, and supplies the realigned digital image data RGB to the data driver 330.

The gate control signal GCS includes a gate start pulse GSP, gate shift clock GSC, gate output enable signal GOE, start signal Vst, and gate clock GCLK. In addition, the gate control signal GCS can include control signals for controlling the shift register 350.

The data control signal DCS includes a source start pulse SSP, source shift clock signal SSC, source output enable signal SOE, and polarity control signal POL.

The data driver 330 supplies data voltage to the data lines DL of the display panel 310. In detail, the data driver 330 converts the image data RGB input from the controller 340 into an analog data voltage and supplies the data voltage to the data lines DL.

The gate driver 320 can include a shift register 350. The shift register 350 sequentially supplies gate pulses to the gate lines GL for one frame using a start signal and gate clock transmitted from the controller 340. In this case, one frame means a time period during which one image is output through the display panel 310. The gate pulse has a turn-on voltage that can turn on the switching element (thin film transistor) disposed in the pixel P.

In addition, the shift register 350 supplies a gate-off signal capable of turning off the switching element to the gate line GL during the remaining period of the one frame in which the gate pulse is not supplied. Hereinafter, the gate pulse and gate-off signal are collectively referred to as a scan signal (SS or Scan).

According to an embodiment of the present disclosure, the gate driver 320 can be mounted in the display panel 310. In this way, the structure in which the gate driver 320 is directly mounted in the display panel 310 is called a gate in panel GIP structure.

The gate driver 320 can include a plurality of thin film transistors. A plurality of thin film transistors can be disposed in the shift register 350.

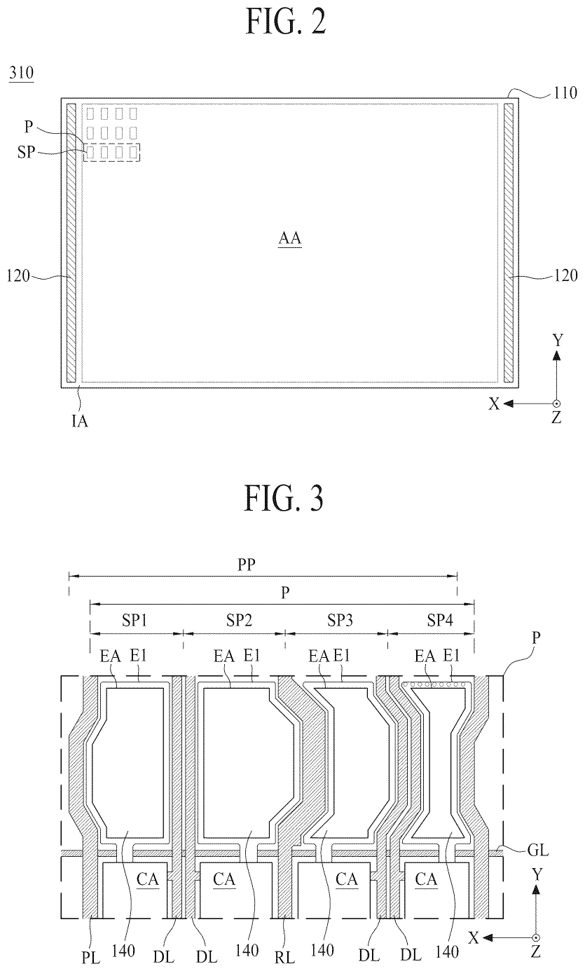

FIG. 2 is a schematic diagram of one embodiment of the display panel 310. FIG. 2 shows an organic light emitting display panel as an example of a display panel 310 applied to the display apparatus 1100. The display apparatus 1100 of FIG. 1, which includes an organic light emitting display panel as the display panel 310, can be called an organic light emitting display apparatus.

Referring to FIG. 2, the display panel 310 can include a substrate 110 and pixels P on the substrate 110.

According to an embodiment of the present disclosure, glass substrate or a plastic substrate can be used as the substrate 110. The substrate 110 can be divided into a display area (or active area) AA and a non-display area (or inactive area) IA. The display panel 310 can include a display area AA and a non-display area IA. The non-display area IA can surround the display area AA entirely or only in part.

The display area AA is an area where an image is displayed and can be referred to as a pixel array area, active area, pixel array unit, display unit, or screen. The display area AA includes a plurality of pixels P.

The plurality of pixels P can be aligned along each of a first direction (e.g., direction X) and a second direction (e.g., direction Y) crossing the first direction X. For example, the first direction X can be referred to as a first longitudinal direction, a long-side longitudinal direction, a horizontal direction, or a first horizontal direction of the substrate 110. In addition, the second direction Y can be referred to as a second longitudinal direction, a short-side longitudinal direction, a vertical direction, or a second horizontal direction of the substrate 110.

Each of the plurality of pixels P can be a unit area where light is actually emitted. For example, each of the plurality of pixels P can be aligned to have a pixel pitch PP (see FIG. 3) along the first direction X. For example, the pixel pitch PP can be defined as a size of each of the plurality of pixels P based on the first direction X, a distance between one sides of each of two adjacent pixels P along the first direction X, or a distance between centers of two adjacent pixels P along the first direction X.

Each of the plurality of pixels P can include a plurality of adjacent subpixels SP. For example, a plurality of subpixels SP can constitute one pixel P.

The non-display area IA is an area where images are not displayed. The non-display area IA can include at least one of a peripheral circuit area, a signal supply area, an inactive area, and a bezel area. The non-display area IA can be referred to as, for example, a peripheral circuit area, a signal supply area, an inactive area, or a bezel area.

The non-display area IA can be configured to surround the display area AA. The display panel 310 can include a peripheral circuit unit 120 disposed in the non-display area IA. The substrate 110 can include an area for a peripheral circuit unit 120 in the non-display area IA. The peripheral circuit unit 120 can include a gate driving circuit connected to a plurality of subpixels SP. The peripheral circuit unit 120 can be a gate driver 320. For example, FIG. 1 illustrates a display apparatus 1100 that includes a gate driver 320, which is a gate driving circuit, as a peripheral circuit unit 120.

FIG. 3 is a plan view showing the planar structure of the pixel P shown in FIG. 2.

Referring to FIGS. 2 and 3, in the display panel 310 of the display apparatus 1100 according to an embodiment of the present disclosure, each of the plurality of pixels P can include, for example, four subpixels SP1, SP2, SP3, SP4.

In an embodiment of the present disclosure, the pixel P can include a first subpixel SP1, a second subpixel SP2, a third subpixel SP3, and a fourth subpixel SP4, which are adjacent to each other along the first direction X. For example, each of the plurality of pixels P includes a red first subpixel SP1, a white second subpixel SP2, a green third subpixel SP3, and a blue fourth subpixel SP4. However, an embodiment of the present disclosure is not limited thereto. For example, according to an embodiment of the present disclosure, each of the first to fourth subpixels SP1 to SP4 can be configured to have different sizes, areas or colors.

Each of the first subpixel SP1, the second subpixel SP2, the third subpixel SP3, and the fourth subpixel SP4 can include an emission area EA and a circuit area CA. The emission area EA emits light.

The emission area EA can be disposed on one side or upper side of the subpixel area. The emission areas EA of each of the first subpixel SP1, the second subpixel SP2, the third subpixel SP3, and the fourth subpixel SP4 can have different sizes or areas. According to an embodiment of the present disclosure, the emission area EA can be referred to as an opening area or a light emitting area.

According to an embodiment of the present disclosure, among the emission areas EA of each of the first subpixel SP1, the second subpixel SP2, the third subpixel SP3, and the fourth subpixel SP4, the emission area EA of the second subpixel SP2 can have the largest size, and the emission area EA of the fourth subpixel SP4 can have the smallest size. The emission area EA of the first subpixel SP1 can be smaller than the emission area EA of the second subpixel SP2, and can be larger than the emission area EA of each of the third subpixel SP3 and fourth subpixels SP4. In addition, the emission area EA of the third subpixel SP3 can be larger than the emission area EA of the fourth subpixel SP4. However, an embodiment of the present disclosure is not limited thereto.

According to an embodiment of the present disclosure, in each of the first subpixel SP1, the second subpixel SP2, the third subpixel SP3, and the fourth subpixel SP4, the circuit area CA can be spatially separated from the emission area EA. For example, the circuit area CA can be disposed on the other side or lower side of the subpixel area. In detail, the circuit area CA can be a non-emitting area or a non-opening area. However, an embodiment of the present disclosure is not limited thereto.

Further, at least a portion of the circuit area CA can overlap the emission area EA. For example, in each subpixel SP1, SP2, SP3, and SP4, the circuit area CA can overlap the entire emission area EA or can be disposed below the emission area EA. According to an embodiment of the present disclosure, the emission area EA can extend to an area over the circuit area CA, and the entire circuit area CA can overlap the emission area EA.

Each of the plurality of pixels P can include a light transmitting portion disposed around the periphery of at least one of the emission area EA and circuit area CA of each of the first subpixel SP1, the second subpixel SP2, the third subpixel SP3, and the fourth subpixel SP4. For example, each of the plurality of pixels P has emission areas EA corresponding to each of the plurality of subpixels SP1, SP2, SP3, SP4, and light transmitting portions disposed around each of the plurality of subpixels SP1, SP2, SP3, SP4. In this case, the display apparatus can realize a transparent display apparatus due to light transmission through the light transmitting portions. A transparent display apparatus including an organic light emitting display panel can be referred to as a transparent organic light emitting display apparatus.

Referring to FIG. 3, between the first subpixel SP1 and the second subpixel SP2, and between the third subpixel SP3 and the fourth subpixel SP4, respectively, two data lines DL extending along the second direction Y can be disposed in parallel to each other. A gate line GL extending along the first direction X can be disposed between the emission area EA and the circuit area CA of each of the first subpixel SP1, the second subpixel SP2, the third subpixel SP3, and the fourth subpixel SP4. A pixel power line PL extending along the second direction Y can be disposed on one side of the first subpixel SP1 or the fourth subpixel SP4. A reference line RL extending along the second direction Y can be disposed between the second subpixel SP2 and the third subpixel SP3. The reference line RL can be used as a sensing line to externally sense changes in the characteristics of the driving thin film transistor disposed in the circuit area CA and/or changes in the characteristics of the light emitting device during the sensing driving mode of the pixel P.

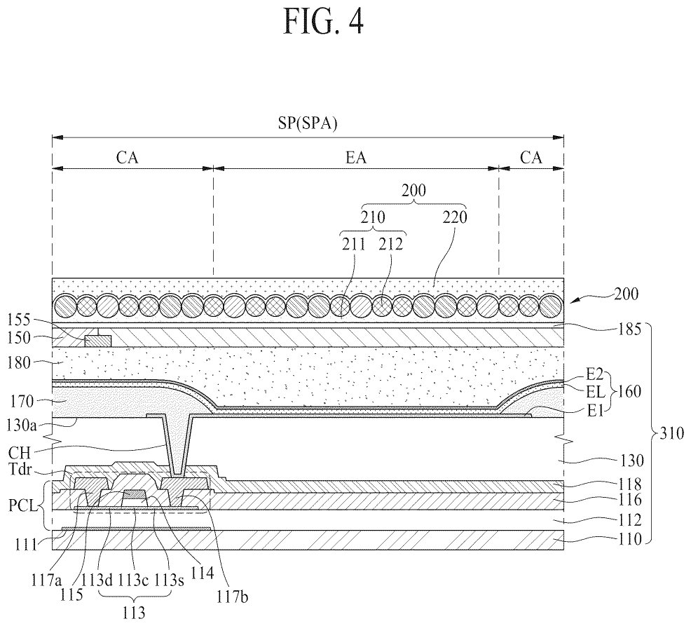

FIG. 4 is a cross-sectional view showing the cross-sectional structure of one subpixel according to an embodiment of the present disclosure.

Referring to FIGS. 3 and 4, the display apparatus 1100 according to an embodiment of the present disclosure can include a substrate 110, an encapsulation layer 180, and a coherence prevention layer 200. For example, the organic light emitting display apparatus 1100 or display panel 310 according to an embodiment of the present disclosure can include a substrate 110, an encapsulation layer 180, and a coherence prevention layer 200.

The substrate 110 can be referred to as a first substrate, a base substrate, a lower substrate, a glass substrate, a plastic substrate, a base member, or the like. According to an embodiment of the present disclosure, glass or plastic can be used as the substrate 110. As the plastic, a transparent plastic with flexible properties, for example, polyimide, can be used. When polyimide is used as the substrate 110, considering that a high temperature deposition process is performed on the substrate 110, a heat-resistant polyimide that can withstand high temperatures can be used.

A pixel circuit layer PCL, a planarization layer 130, and an organic light emitting element 160 can be disposed on the substrate 110. The pixel circuit layer PCL can include a buffer layer 112, a pixel circuit, and a protection layer 118.

The buffer layer 112 can be disposed on the entire first side or front side of the substrate 110. The buffer layer 112 can serve to block materials contained in the substrate 110 from diffusing into the transistor layer during a high temperature process during the manufacturing process of a thin film transistor. The buffer layer 112 can also serve to prevent external moisture or humidity from penetrating into the organic light emitting element 160. Optionally, the buffer layer 112 can be omitted.

The pixel circuit can include a driving thin film transistor Tdr disposed in the circuit area CA of each subpixel SP. The driving thin film transistor Tdr can include an active layer 113, a gate insulating layer 114, a gate electrode 115, an interlayer insulating layer 116, a drain electrode 117a, and a source electrode 117b. According to an embodiment of the present disclosure, the subpixel SP can be any one of the first subpixel SP1, the second subpixel SP2, the third subpixel SP3, and the fourth subpixel SP4.

The active layer 113 can comprise a semiconductor material based on any one of amorphous silicon, polycrystalline silicon, oxide, and organic material. The active layer 113 can include a channel region 113c, a drain region 113d, and a source region 113s.

The gate insulating layer 114 is disposed on the active layer 113. For example, the gate insulating layer 114 can be disposed in an island shape only on the channel region 113c of the active layer 113. However, an embodiment of the present disclosure is not limited thereto and the gate insulating layer 114 can be disposed on the entire surface of the substrate 110 or the buffer layer 112 including the active layer 113.

The gate electrode 115 is disposed on the gate insulating layer 114 to overlap the channel region 113c of the active layer 113.

The interlayer insulating layer 116 can be formed on the gate electrode 115 and the drain region 113d and source region 113s of the active layer 113. The interlayer insulating layer 116 can be formed on the entire front surface of the substrate 110 or the buffer layer 112. For example, the interlayer insulating layer 116 can comprise an inorganic material or an organic material.

The drain electrode 117a can be disposed on the interlayer insulating layer 116 to be electrically connected to the drain region 113d of the active layer 113. The source electrode 117b can be disposed on the interlayer insulating layer 116 to be electrically connected to the source region 113s of the active layer 113.

The pixel circuit can further include at least one capacitor disposed in the circuit area CA together with the driving thin film transistor Tdr, and at least one switching thin film transistor.

The display apparatus 1100 according to an embodiment of the present disclosure can further include a light shielding layer 111. The light shielding layer 111 can be disposed on the substrate 110 to overlap the active layer 113 to minimize or prevent changes in the threshold voltage of the thin film transistor due to external light. According to an embodiment of the present disclosure, the light shielding layer 111 can be disposed under the active layer 113 of the driving thin film transistor Tdr or the switching thin film transistor.

A protecting layer 118 can be disposed on the pixel circuit. For example, the protecting layer 118 can be configured to cover the drain electrode 117a and the source electrode 117b of the driving thin film transistor Tdr and the interlayer insulating layer 116. For example, the protecting layer 118 can be made of an inorganic insulating material and can also be referred to as a passivation layer or an interlayer insulation layer.

The planarization layer 130 can be disposed on the pixel circuit layer PCL. The planarization layer 130 can be formed in the entire display area and the non-display area excluding the pad area. For example, the planarization layer 130 can include an extension portion that extends from the display area toward the remaining non-display area excluding the pad area. Accordingly, the planarization layer 130 can have a size larger than the size of the display area.

According to an embodiment of the present disclosure, the planarization layer 130 is formed to have a relatively thick thickness to provide a planar surface 130a on the pixel circuit layer (PCL). For example, the planarization layer 130 can be made of an organic material.

The organic light emitting element 160 can be disposed in the emission area EA of each subpixel SP. According to an embodiment of the present disclosure, the organic light emitting element 160 can include a first electrode E1, an emission layer EL, and a second electrode E2.

According to an embodiment of the present disclosure, the first electrode E1, the light emitting layer EL, and the second electrode E2 can be configured to emit light to the opposite side of the substrate 110 according to a top emission manner. Alternatively, the first electrode E1, the light emitting layer EL, and the second electrode E2 can be configured to emit light toward the substrate 110 according to a bottom emission manner.

Hereinafter, for convenience of explanation, embodiments of the present disclosure will be described focusing on the display apparatus 1100 including the organic light emitting element 160 configured to emit light to the opposite side of the substrate 110 according to the top emission method.

The first electrode E1 can be formed on the planarization layer 130 of the subpixel area SPA and electrically connected to the source electrode 117b of the driving thin film transistor Tdr. One end of the first electrode E1 adjacent to the circuit area CA can be connected to the source electrode 119s of the driving thin film transistor Tdr through the electrode contact hole CH provided in the planarization layer 130 and the protecting layer 118.

The light emitting layer EL is formed on the first electrode E1 and can be in direct contact with the first electrode E1.

According to an embodiment of the present disclosure, the light emitting layer EL can include two or more organic light emitting layers in order to emit white light. For example, the light emitting layer EL can include a first organic light emitting layer and a second organic light emitting layer for emitting white light by mixing a first light and a second light.

The second electrode E2 is formed on the light emitting layer EL and can be in direct contact with the light emitting layer EL. The second electrode E2 can be disposed on the light emitting layer EL to have a relatively thin thickness compared to the light emitting layer EL.

According to an embodiment of the present disclosure, for top emission, the first electrode E1 has a structure capable of reflecting incident light emitted from the light emitting layer EL to a direction opposite to the substrate 110. In order to reflect incident light emitted from the light emitting layer EL to a direction opposite to the substrate 110, the first electrode E1 can include a metal with high reflectivity. For example, the first electrode E1 can include at least one selected from aluminum (Al), silver (Ag), molybdenum (Mo), gold (Au), magnesium (Mg), calcium (Ca), or barium (Ba) or can include alloy thereof. In addition, the first electrode E1 can have a single-layer structure or a multi-layer structure. The first electrode E1 can be an anode.

The second electrode E2 can have light transparency. According to an embodiment of the present disclosure, the second electrode E2 can have both light transparency and light reflection property. For example, the second electrode E2 can have a multilayer structure including a layer made of transparent conductive oxide TCO and a layer made of a metal with a low work function. The second electrode E2 can be a cathode.

The display apparatus 1100 according to an embodiment of the present disclosure can include a bank layer 170. The bank layer 170 can be disposed on the edge of the first electrode E1 and on the planarization layer 130. The bank layer 170 can include a transparent material or an opaque material. For example, the bank layer 170 can be a transparent bank layer or a black bank layer. For example, the bank layer 170 can include a black pigment, and in this case, the bank layer 170 can serve as a light blocking member between adjacent subpixels SP.

The encapsulation layer 180 can be formed on the substrate 110 to cover the organic light emitting element 160. The encapsulation layer 180 can be formed on the second electrode E2. For example, the encapsulation layer 180 can cover the display area. The encapsulation layer 180 can serve to protect the thin film transistor and the light emitting layer EL from external shock and prevent oxygen, moisture, or foreign particles from penetrating into the light emitting layer EL.

According to an embodiment of the present disclosure, the encapsulation layer 180 can include a plurality of inorganic encapsulation layers. The encapsulation layer 180 can further include at least one organic encapsulation layer interposed between the plurality of inorganic encapsulation layers.

The display apparatus 1100 according to an embodiment of the present disclosure can include a color filter layer 150. The color filter layer 150 can be disposed in a direction in which light is emitted from the organic light emitting element 160. According to an embodiment of the present disclosure, the color filter layer 150 can be disposed on the opposite side of the substrate 110 relative to the organic light emitting element 160.

The color filter layer 150 can be disposed on the organic light emitting element 160 to overlap at least one light emitting area EA. According to an embodiment of the present disclosure, the color filter layer 150 can be disposed on the encapsulation layer 180.

The color filter layer 150 can have a size larger than the emission area EA. For example, an edge portion of the color filter layer 150 can overlap the bank layer 170. According to an embodiment of the present disclosure, the color filter layer 150 can have a size corresponding to the entire subpixel area SPA of each subpixel SP, thereby reducing light leakage between adjacent subpixels SP.

According to an embodiment of the present disclosure, the color filter layer 150 can be configured to transmit light having a wavelength correspond to the color of the subpixel SP. For example, as shown in FIG. 3, when one pixel P includes first, second, third, and fourth subpixels SP1, SP2, SP3, and SP4, the color filter layer 150 can include a red color filter provided in the first subpixel SP1, a green color filter provided in the third subpixel SP3, and a blue color filter provided in the fourth subpixel SP4. The second subpixel SP2 may not include a color filter or can include a transparent material layer for step compensation, thereby emitting white light.

According to an embodiment of the present disclosure, the color filter layer 150 can be formed directly on the upper surface of the encapsulation layer 180 so as to overlap the emission area EA. For example, the color filter layer 150 can directly contact the upper surface of the encapsulation layer 180. However, an embodiment of the present disclosure is not limited thereto, and a transparent adhesive member can be disposed between the encapsulation layer 180 and the color filter layer 150.

The display apparatus 1100 according to an embodiment of the present disclosure can include a black matrix 155 disposed between color filters of the color filter layer 150.

The black matrix 155 can be arranged to overlap the remaining areas excluding the emission area EA of each subpixel SP. However, the embodiment of the present disclosure is not limited to this, and the remaining area excluding the emission area EA of each subpixel SP can include a stacked structure of at least two or more color filters instead of the black matrix 155. there is. For example, the remaining area excluding the emission area EA of each subpixel SP can include a stacked structure of at least two color filters among a red color filter, a green color filter, and a blue color filter. The stacked structure of at least two color filters can replace the black matrix 155 and prevent color mixing between adjacent subpixels SP.

Referring to FIG. 4, an overcoating layer 185 can be disposed on the color filter layer 150. The overcoating layer 185 can protect the color filter layer 150 and can planarize the upper portion of the color filter layer 150. The overcoating layer 185 can also be referred to as a protective layer. The overcoating layer 185 can be omitted.

According to an embodiment of the present disclosure, a stack from the substrate 110 to the color filter layer 150 can be called a display panel 310. Referring to FIG. 4, a stack from the substrate 110 to the overcoating layer 185 can be referred to as a display panel 310. According to an embodiment of the present disclosure, the display panel 310 can include an organic light emitting element 160.

The display apparatus 1100 according to an embodiment of the present disclosure includes a coherence prevention layer 200 disposed on the display panel 310.

The coherence prevention layer 200 prevents a generation of diffraction interference patterns caused by coherence of light wavelengths when external light is incident on the display panel 310 and reflected back. Hereinafter, the diffraction interference pattern can also be referred to a diffraction pattern, reflection diffraction mura, rainbow mura, rainbow speckle pattern, or circular ring pattern. According to an embodiment of the present disclosure, the diffraction pattern, reflection diffraction mura, rainbow mura, rainbow speckle pattern, and circular ring pattern are all different terms for “diffraction interference patterns” caused by the coherence of reflected light.

Hereinafter, the diffraction interference patterns, which is generated by the coherence of reflected light and sometimes referred to as diffraction pattern or reflection diffraction mura, will be described.

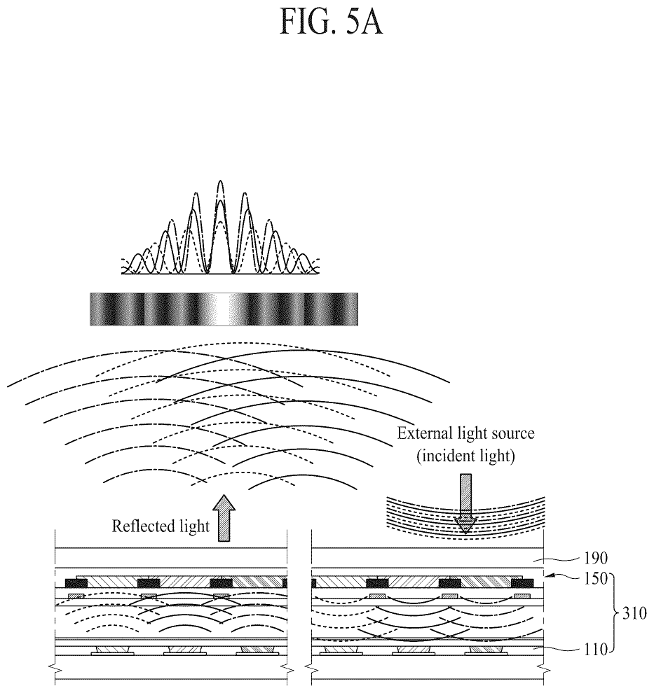

FIG. 5A is a schematic diagram illustrating a coherence of reflected light generated in a display apparatus according to a reference example and a mechanism of generating diffraction patterns. FIG. 5B is a picture illustrating a diffraction pattern caused by an external light source in a display apparatus according to a reference example.

Referring to FIG. 5A, a display apparatus according to a reference example includes a display panel 310 and a cover window 190. An external light enters into the display panel 310 through the cover window 190. As the cover window 190, a glass substrate or a transparent plastic substrate can be used.

In the display apparatus according to the reference example, coherence of waves can occur in a process in which external light generated from an external light source and incident on the display panel 310 is reflected back in the display panel 310. The pixels, electrodes, and color filters regularly aligned in the display panel 310 and the apertures created by their alignment can serve as slits that generate diffraction of light, and coherence is generated by the diffracted light.

Preferably, coherence means that multiple waves have a certain phase relationship and are in a state where interference is possible. Coherence is a property that causes waves to exhibit interference. The phenomenon of interference due to coherence is well known in optics as Young's double-slit interference experiment. When two or more waves are combined, destructive or constructive interference occurs depending on the phases of the two waves. The better the coherence, the more likely the interference phenomenon occurs.

A display apparatus, for example, an organic light emitting display apparatus, includes a plurality of pixels P or sub-pixels SP, which are arranged regularly and repeatedly. As a result, electrodes, color filters, wiring, black matrices, or the like, included in the pixel are arranged regularly and repeatedly, and accordingly, openings or apertures are regularly arranged between them. Regularly arranged openings or apertures serve as slits in Young's double-slit interference experiment, and as a result, coherence is generated regularly and wave interference occurs.

In more detail, light travels in a straight line, and light passing through a narrow gap will take a path that deviates from the law of refraction due to the phenomenon of a diffraction. When external light is incident on a display apparatus, for example, an organic light emitting display apparatus and then reflected back, a specific interference pattern appears as shown in FIG. 5B due to a diffraction phenomenon.

FIG. 5B is a picture of a diffraction interference pattern generated when a point light source is shined on the display apparatus of the reference example when the display apparatus of the reference example is in a turned-off state.

Referring to FIG. 5B, the reason for occurrence of the characteristic interference pattern is that the pixel of the display apparatus or the aperture existing between the pixels act as narrow gaps that causes diffraction. As a result, light incident from the outside and reflected light are converted into diffracted light by the narrow gaps, and they reinforce or destructively interfere with each other, creating a spectral dispersion pattern or diffraction interference pattern.

These diffraction interference patterns can cause a decrease in the black image quality of display apparatus, especially in organic light emitting displays, and act as a display quality deterioration factor. In particular, when such diffraction interference patterns occur in the display apparatus or organic light emitting display apparatus used in automobiles, information visibility deteriorates when the driver looks at display apparatus such as a cluster or navigation, which can also affect driving safety.

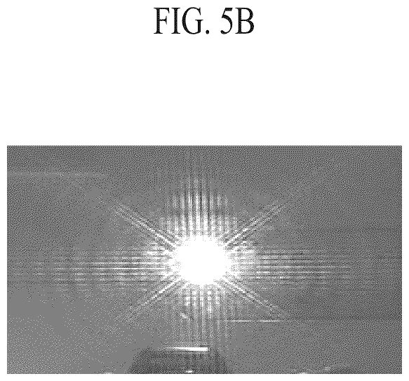

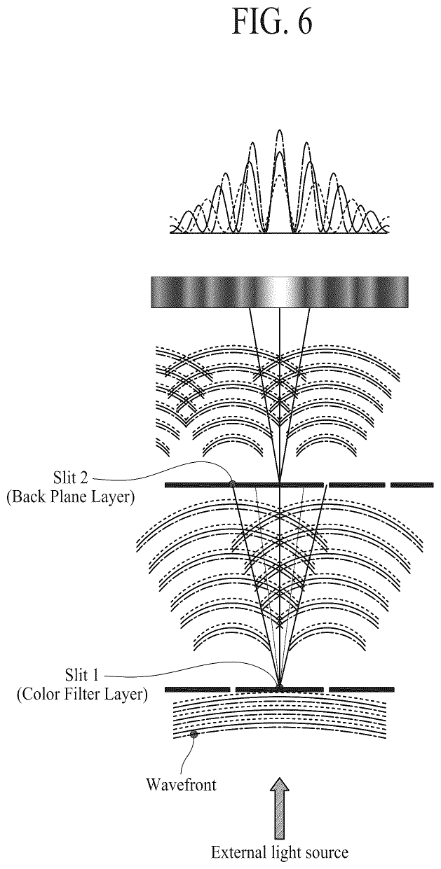

FIG. 6 is a schematic diagram illustrating a mechanism by which coherence and diffraction patterns occur by light passing through a slit or an aperture. In more detail, FIG. 6 is a diagram matching the display panel 310 to Young's double-slit interference experiment.

Referring to FIG. 6, the light transmitting portion of the color filter layer of the display panel 310 can correspond to a first slit (Slit1) of Young's double-slit interference experiment model. In addition, the back plane layer comprising the pixel circuit layer PCL can correspond to the second slit (Slit2) of Young's double-slit interference experiment model. Therefore, when a wave having a type of wave-front shown in FIG. 6 is incident into the display panel 310, interference and coherence such as in Young's double-slit interference experiment can occur.

When a display apparatus or a display panel 310 is not driven or in an OFF state, external light incident from the outside can be reflected inside the display apparatus or the display panel 310 and the reflected light can be emitted back to the outside. Diffraction occurs when the reflected light passes through regularly aligned apertures inside the display panel 310. When coherence of waves occurs by the diffracted light, as shown in FIG. 5B, a rainbow mura or rainbow speckle pattern that spreads radially and has rainbow colors can be generated, or a radial circular ring pattern can be generated. The rainbow mura, the rainbow speckled pattern or the circular ring pattern can degrade the black visibility or the black viewing characteristics of the display apparatus.

According to an embodiment of the present disclosure, the generation of diffraction interference patterns generated on the display surface of the display apparatus 1100 can be suppressed or prevented by the coherence prevention layer 200 instead of using a polarizer or circular polarizer.

In detail, according to an embodiment of the present invention, a coherence prevention layer 200 is disposed on the display panel 310 in order to prevent the occurrence of a diffraction pattern, a reflection diffraction mura, a rainbow mura, a rainbow speckle pattern, or a circular ring pattern, or the like, when an external light is incident into the display panel 310 and then reflected back (see FIG. 4).

According to an embodiment of the present disclosure, the coherence prevention layer 200 includes a refractive index particle layer 210 and a filling layer 220 on the refractive index particle layer 210. The refractive index particle layer 210 includes a light-transmissive matrix 211 and refractive index particles 212 dispersed in the light-transmissive matrix 211.

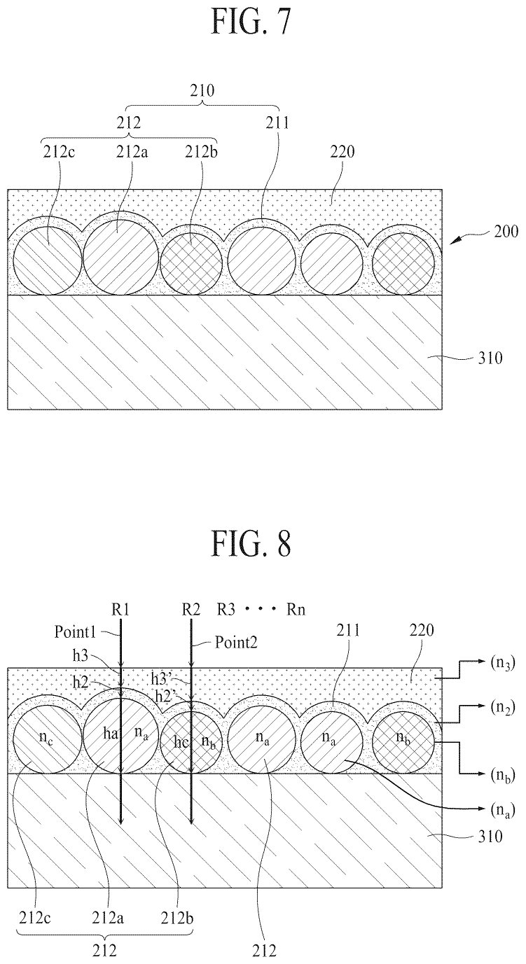

FIG. 7 is a partial enlarged view of the coherence prevention layer 200 shown in FIG. 4.

Referring to FIG. 7, according to an embodiment of the present disclosure, the refractive index particles 212 can include a first particle 212a and a second particle 212b. The first particle 212a can have a first refractive index, and the second particle 212b can have a second refractive index. According to an embodiment of the present disclosure, the first refractive index and the second refractive index can be different from each other. However, an embodiment of the present disclosure is not limited thereto, and the first refractive index and the second refractive index can be the same.

According to an embodiment of the present disclosure, the refractive index particles 212 and the filling layer 220 can have different refractive indices. As a result, a path difference occurs depending on the path along which the external light is incident, and a difference occurs in the propagation speed of the external light. In addition, even when external light is reflected and emitted from the inside of the display panel 310, a path difference occurs depending on the reflection path, and a difference occurs in the propagation speed of the reflected light. Due to this difference in path and propagation speed, the coherence of reflected light is reduced or prevented, thereby suppressing or preventing the generation of a diffraction pattern caused by reflected light. As a result, the occurrence of reflection diffraction mura, rainbow mura, rainbow speckle pattern, or circular ring pattern, or the like, is suppressed or prevented in the present devices.

FIG. 8 is a schematic diagram explaining the path difference of light passing through the coherence prevention layer 200 according to an aspect of the present disclosure.

When light passes through a medium, a path difference occurs. Hereinafter, as for an example, with reference to FIG. 8, the path difference of light perpendicularly incident on the coherence prevention layer 200 will be described.

First, the optical path length (OPL) at a first point (Point 1) and at a second point (Point 2) in FIG. 8 is calculated. Referring to FIG. 8, the optical path length (OPL) of the first point (Point 1) is indicated by R1, and the optical path length (OPL) of the second point (Point 2) is indicated by R2.

Since light is incident vertically, the optical path length (OPL) can be defined as “n×d”. Here, n is the refractive index of the medium, and d is the distance.

In FIG. 8, the refractive index of the light-transmissive matrix 211 is n₂, the refractive index of the filling layer 220 is n₃, and the refractive index of the first particle 212a of the refractive index particles 212 is nₐ, and the refractive index of the second particle 212b is n_{b}.

When light is incident on the first point (Point 1) and passes through the coherence prevention layer 200, the distance of the filling layer 220 through which the light incident to the first point (Point 1) passes is h₃, the distance passing through the light-transmissive matrix 211 is h₂, and the distance passing through the first particle 212a is ha. In addition, when light is incident on the second point (Point 2) and passes through the coherence prevention layer 200, the distance of the filling layer 220 through which the light incident to the second point (Point 2) passes is h₃′, the distance passing through the light-transmissive matrix 211 is h₂′, and the distance passing through the first particle 212a is h_{b}.

When the optical path length (OPL) of light incident on the first point (Point 1) and passing through the coherence prevention layer 200 is referred to as R1, R1 can be calculated according to the following Equation 1.

$$R 1 = {n}_{3} ( {h}_{3} ) + {n}_{2} ( {h}_{2} ) + {n}_{a} ( {h}_{a} ) \qquad [ Equation 1 ]$$

When the optical path length (OPL) of light incident on the second point (Point 2) and passing through the coherence prevention layer 200 is referred to as R2, R2 can be calculated according to the following Equation 2.

$$R 2 = {n}_{3} ( {h}_{3}^{′} ) + {n}_{2} ( {h}_{2}^{′} ) + {n}_{b} ( {h}_{b} ) \qquad [ Equation 2 ]$$

The difference between the optical path length (OPL) of light passing through the coherence prevention layer 200 at the first point (Point 1) and the optical path length (OPL) of light passing through the coherence prevention layer 200 at the second point (Point 2) can be calculated according to the following Equation 3.

$$R 1 - R 2 = {n}_{3} ( {h}_{3} - {h}_{3}^{′} ) + {n}_{2} ( {h}_{2} - {h}_{2}^{′} ) + {n}_{a} * {h}_{a} - {n}_{b} * {h}_{b} \qquad [ Equation 3 ]$$

According to an embodiment of the present disclosure, the optical path length (OPL) R1 of the light passing through the coherence prevention layer 200 at the first point (Point 1) and the optical path length (OPL) R2 of the light passing through the coherence prevention layer 200 at the second point (Point 2) is different, and accordingly, “R1-R2” has a predetermined value.

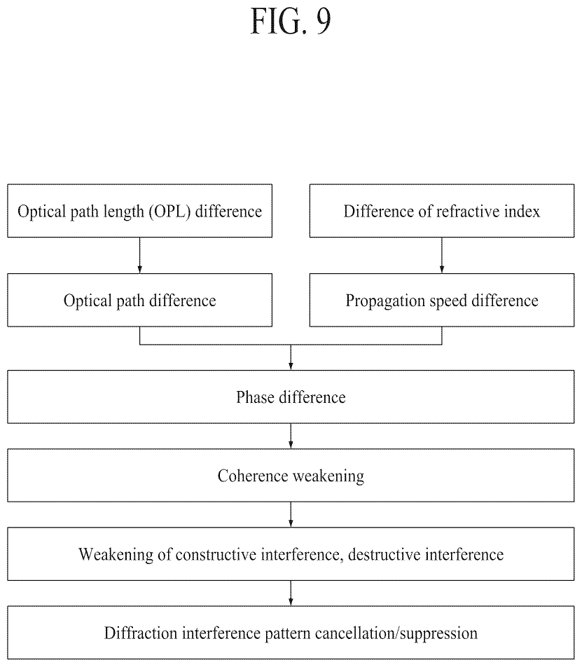

In this way, when the optical path length of the light passing through the coherence prevention layer 200 is different depending on the point at which the light is incident, the diffraction interference pattern can be canceled or suppressed by a mechanism as shown in FIG. 9.

FIG. 9 is a schematic diagram explaining a mechanism of diffraction interference pattern cancellation or suppression.

Referring to FIG. 9, when the optical path length (OPL) of light passing through the coherence prevention layer 200 is different depending on the point at which light is incident, an optical path difference occurs in the light passing through the coherence prevention layer 200 for each location. Accordingly, the phase of light varies depending on the position where the light passes through the coherence prevention layer 200. As a result, coherence is weakened, constructive interference and destructive interference are weakened, and diffraction interference patterns are thereby canceled, prevented or suppressed.

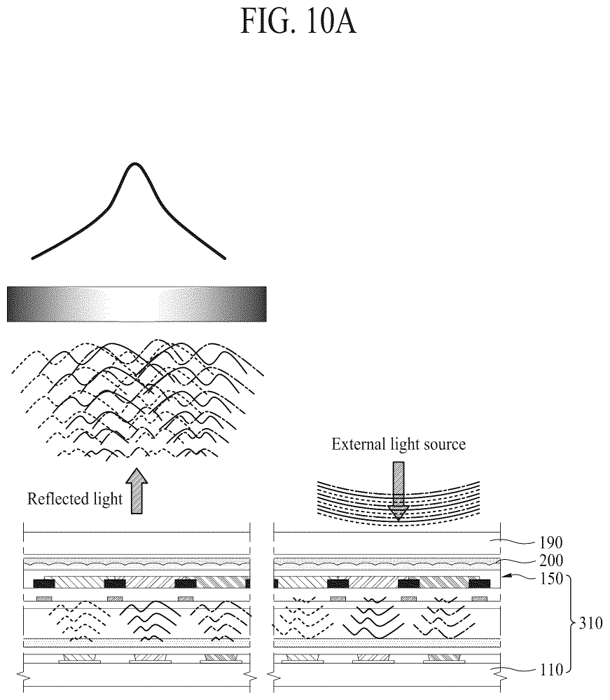

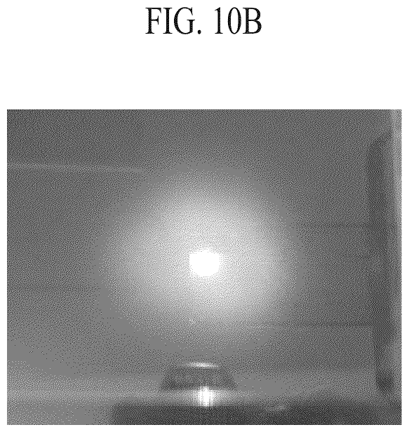

FIG. 10A is a schematic diagram illustrating a mechanism by which coherence of reflected light is suppressed in the display apparatus 1100 according to an embodiment of the present disclosure.

Referring to FIG. 10A, the display apparatus 1100 can further include a cover window 190, and external light can be incident through the cover window 190. As the cover window 190, a glass substrate or a transparent plastic substrate can be used.

In the process that the incident external light passes through the coherence prevention layer 200, the optical path length (OPL) varies depending on the point of incidence of the light, resulting in an optical path differences. Accordingly, the phase of light varies depending on the point of incidence, weakening coherence of wave and weakening constructive interference and destructive interference.

In addition, light reflected from the inside of the display panel 310 and emitted to the outside passes through the coherence prevention layer 200. Therefore, even if coherence occurs in the process of light reflection inside the display panel 310, reflected light passes through the coherence prevention layer 200 when it is emitted outside, thus the optical path length (OPL) varies depending on the location as the emitting light passes through the coherence prevention layer 200, resultingly a difference in optical path occurs. Accordingly, the phases of light are different from each other, the coherence of waves is weakened, and constructive interference and destructive interference are weakened. As a result, when reflected light is emitted to the outside, the generation of a diffraction pattern, reflection diffraction mura, rainbow mura, rainbow spot pattern, or circular ring pattern, or the like, is suppressed.

FIG. 10B is a picture showing that the diffraction pattern caused by an external light source is reduced in a display apparatus according to an embodiment of the present disclosure.

In detail, FIG. 10B is a picture of light reflected when a point light source is shined onto the display apparatus 100 when the display apparatus 100 is in an off state, according to an embodiment of the present disclosure.

Referring to FIG. 10B, it can be seen that while it is recognized that a point light source has illuminated the display apparatus 100, a characteristic interference pattern as shown in FIG. 5B is not detected. As such, according to an embodiment of the present disclosure, in the display apparatus 1100 including the coherence prevention layer 200, it can be confirmed that a spectral dispersion pattern, a diffraction interference pattern, a reflection diffraction mura, a rainbow mura, rainbow speckle patterns, or circular ring patterns, due to reflection of external light, does not occur.

According to an embodiment of the present disclosure, in order for variation of the optical path length (OPL), the refractive indices of the light-transmissive matrix 211, the refractive index particles 212, and the filling layer 220 included in the coherence prevention layer 200 can be designed to be different from each other.

According to an embodiment of the present disclosure, the difference in refractive index between the refractive index particles 212 and the filling layer 220 can be designed to be in a range of 0.05 to 0.40.

When the difference in refractive index between the refractive index particles 212 and the filling layer 220 is less than 0.05, the effect of suppressing coherence by the coherence prevention layer 200 can be reduced. As a result, the effect of suppressing the generation of a diffraction interference pattern such as reflection diffraction mura, rainbow mura, rainbow speckle pattern, or circular ring pattern, by the coherence prevention layer 200 can is reduced.

On the other hand, when the difference in refractive index between the refractive index particles 212 and the filling layer 220 exceeds 0.40, the occurrence of diffraction interference patterns can be suppressed by the coherence prevention layer 200, but the light emitted from the pixel is distorted and thus the image displayed on the device 1100 can be distorted. In addition, when the difference in refractive index between the refractive index particles 212 and the filling layer 220 exceeds 0.40, turbidity increases due to the coherence prevention layer 200, and the black image quality of the display apparatus 1100 is deteriorated or visibility of the display apparatus 1100 can be deteriorated.

Therefore, according to an embodiment of the present disclosure, the difference in refractive index between the refractive index particles 212 and the filling layer 220 is designed to be in a range of 0.05 to 0.40.

According to an embodiment of the present disclosure, the light-transmissive matrix 211 is very thin, and thus its influence on the optical path length (OPL) is relatively small. Accordingly, the light-transmissive matrix 211 can be set to be the same as or similar to the refractive index of the refractive index particles 212 or the refractive index of the filling layer 220.

According to an embodiment of the present disclosure, a difference between the refractive index of the light-transmissive matrix 211 and the refractive index of the refractive index particles 212 can be 0.03 or less. In more detail, the difference between the refractive index of the light-transmissive matrix 211 and the refractive index of the refractive index particles 212 can be in a range of 0.01 to 0.03.

According to an embodiment of the present disclosure, a difference between the refractive index of the light-transmissive matrix 211 and the refractive index of the filling layer 220 can be 0.4 or less. In more detail, the difference between the refractive index of the light-transmissive matrix 211 and the refractive index of the filling layer 220 can be in a range of 0.01 to 0.4.

According to an embodiment of the present disclosure, the first particles 212a and the second particles 212b included in the refractive index particle layer 210 can have different refractive indices. The first particle 212a and the second particle 212b can have a refractive index difference in a range of, for example, 0.05 to 0.40.

When the difference in the refractive index of the first particle 212a and the second particle 212b is in a range of 0.05 to 0.40, suppression of diffraction interference pattern generation by the coherence prevention layer 200 can be effectively achieved without distortion of the image. When the difference in refractive index of the first particle 212a and the second particle 212b is in a range of 0.05 to 0.40, a difference in optical path length (OPL) can be generated at an appropriate level by the coherence prevention layer 200.

According to an embodiment of the present disclosure, the first particles 212a and the second particles 212b can have the same particle size or different particle sizes. The particle size can be referred to as a particle diameter. Referring to FIGS. 4 and 7, the first particle 212a and the second particle 212b can have different particle sizes. According to an embodiment of the present disclosure, the diameter of a particle is referred to as a particle size.

According to an embodiment of the present disclosure, the refractive index particles 212 can have a particle diameter of 760 nm to 60 μm. In more detail, the first particle 212a and the second particle 212b can have a particle diameter of 760 nm to 60 μm.

When the particle size of the refractive index particles 212 is smaller than the wavelength of visible light, visible light can pass through the coherence prevention layer 200 without passing through the interior of the refractive index particles 212. Therefore, in order to allow visible light to pass through the refractive index particles 212, the refractive index particles 212 can be designed to be longer than the wavelength of visible light. Considering that the maximum wavelength of visible light is about 760 nm, the refractive index particles 212 can have a particle size of 760 nm or more.

In addition, when the particle size of the refractive index particles 212 exceeds 60 μm, the refractive index particles 212 can be visible to the user. In order to prevent the refractive index particles 212 from being visible to the user, the particle size of the refractive index particles 212 can be designed to be 60 μm or less.

In order for a thin the display apparatus 1100, the thickness of the coherence prevention layer 200 can be made small, and for this purpose, the particle size of the refractive index particles 212 can be adjusted to a predetermined range. According to an embodiment of the present disclosure, in order to reduce the thickness of the display apparatus 1100, the refractive index particles 212 can have an average particle diameter of, for example, 760 nm to 20 μm.

According to an embodiment of the present disclosure, the refractive index particles 212 can further include a third particle 212c having a different refractive index from the first particle 212a and the second particle 212b. The third particle 212c can have a same particle size as the first particle 212a and the second particle 212b, or can have a different particle size.

According to an embodiment of the present disclosure, the refractive index particles 212 can be made of a material having light transparency. The refractive index particles 212 can include, for example, at least one of polymethyl methacrylate (PMMA), polycarbonate (PC), polyethylene terephthalate (PET), polyurethane (PU), polystyrene (PS), nylon, silicone oxide (SiO2), titanium oxide (TiO2), silicon nitride (SixNy), silicon oxynitride (SiON), aluminum oxide (AlOx), aluminum nitride (AlON), zinc oxide (ZnO), tantalum oxide (Ta2O5), magnesium fluoride (MgF2), yttrium oxide (Y2O3), and hafnium oxide (HfO2).

According to an embodiment of the present disclosure, the refractive index particles 212 can be made of a light-transmissive organic material. The refractive index particles 212 can include, for example, at least one of polymethyl methacrylate (PMMA), polycarbonate (PC), polyethylene terephthalate (PET), polyurethane (PU), polystyrene (PS), and nylon.

The first particles 212a, second particles 212b, and third particles 212c can be made of the same material or can be made of different materials.

According to an embodiment of the present disclosure, the refractive index particles 212 can have a refractive index ranging from 1.4 to 2.1, for example. Depending on the type of material and manufacturing conditions for manufacturing the refractive index particles 212, the refractive index of the refractive index particles 212 can vary.

In the coherence prevention layer 200 according to an embodiment of the present disclosure, the light-transmissive matrix 211 serves to fix the refractive index particles 212. Accordingly, the light-transmissive matrix 211 can be referred to as a binder. The light-transmissive matrix 211 can be made of a polymer resin with adhesive properties. In more detail, the light-transmissive matrix 211 can include a photo-polymerizable resin or a thermally polymerizable resin. For example, the light-transmissive matrix 211 can be formed by polymerization of monomers. To polymerize monomers, light can be irradiated (photopolymerization) or heat can be applied (thermal polymerization). For example, UV can be used for photopolymerization.

In addition, to form the light-transmissive matrix 211, curing can be performed after polymerization of the monomer. Curing methods can include photocuring or thermal curing. According to an embodiment of the present disclosure, the light-transmissive matrix 211 can be formed by UV photocuring using ultraviolet rays UV.

The light-transmissive matrix 211 can include at least one of polymethyl methacrylate (PMMA)-based, polycarbonate (PC)-based, polyethylene terephthalate (PET)-based, polyurethane (PU)-based, and polystyrene (PS)-based polymer resins.

The light-transmissive matrix 211 can be made of the same or similar materials as the refractive index particles 212. The light-transmissive matrix 211 can be made of the same family of materials as the refractive index particles 212. Even though the light-transmissive matrix 211 is made of the same or similar material as the refractive index particles 212, the refractive indices of the light-transmissive matrix 211 and the refractive index particles 212 can be made to be different from each other, for example by varying the curing conditions.

The light-transmissive matrix 211 can have a refractive index ranging from 1.4 to 1.9, for example. Depending on the type of material forming the light-transmissive matrix 211 and the process conditions for forming the light-transmissive matrix 211 and the refractive index particle layer 210, the refractive index of the light-transmissive matrix 211 can vary.

According to an embodiment of the present disclosure, the light-transmissive matrix 211 has a relatively thin thickness compared to the refractive index particles 212 or the filling layer 220. The light-transmissive matrix 211 can have a shape or structure that thinly coats the refractive index particles 212. The light-transmissive matrix 211 can have a shape profile identical to that of the refractive index particles 212.

The filling layer 220 is disposed on the refractive index particle layer 210 and serves to flatten the upper surface of the coherence prevention layer 200. The filling layer 220 can be made of polymer resin.

In more detail, the filling layer 220 can include photopolymerizable resin or thermally polymerizable resin. For example, the filling layer 220 can be formed by polymerization of monomers. To polymerize monomers, light can be irradiated (photopolymerization) or heat can be applied (thermal polymerization). For example, UV can be used for photo-polymerization.

In addition, to form the filling layer 220, curing can be performed after polymerization of the monomer. Curing methods can include photocuring or thermal curing. According to an embodiment of the present disclosure, the filling layer 220 can be formed by UV photocuring using ultraviolet rays UV.

The filling layer 220 can include, for example, at least one of polymethyl methacrylate (PMMA)-based, polycarbonate (PC)-based, polyethylene terephthalate (PET)-based, polyurethane (PU)-based, and polystyrene (PS)-based polymer resin.

The filling layer 220 can be made of the same or similar material as the light-transmissive matrix 211. The filling layer 220 can be made of the same family of materials as the light-transmissive matrix 211. Even though the filling layer 220 is made of the same or similar material as the light-transmissive matrix 211, the refractive indices of the filling layer 220 and the light-transmissive matrix 211 can be made to different from each other, for example, by varying the curing conditions.

For example, the filling layer 220 can have a refractive index ranging from 1.4 to 1.9. Depending on the type of material forming the filling layer 220 and the process conditions for forming the filling layer 220, the refractive index of the filling layer 220 can vary.

According to an embodiment of the present disclosure, the refractive index particle layer 210 can have a plurality of lens patterns.

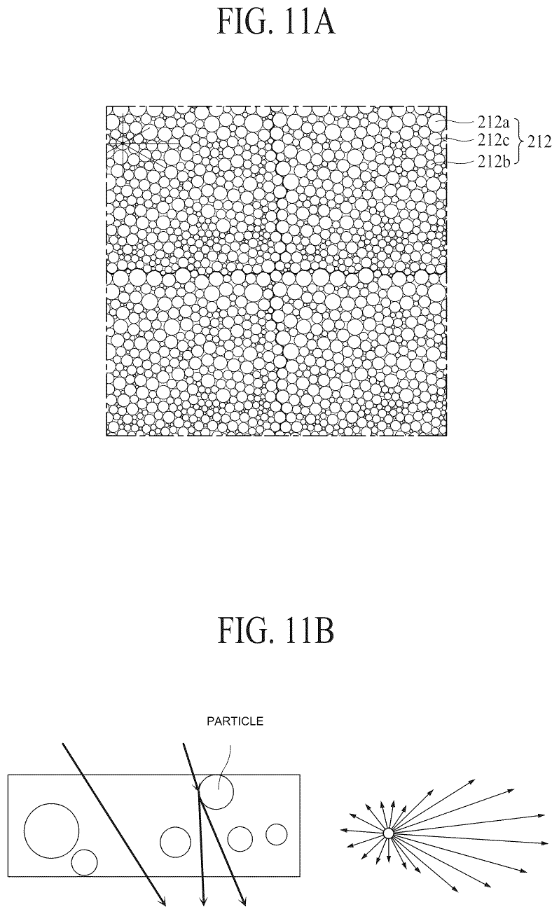

FIG. 11A is a partial plan view of a refractive index particle layer 210 according to an aspect of the present disclosure.

Referring to FIG. 11A, the refractive index particle layer 210 has a plurality of lens patterns resulting from the shape of the refractive index particles 212. The refractive index particle layer 210 can be referred to as having a concavo-convex pattern or a micro lens pattern.

According to an embodiment of the present disclosure, the refractive index particle layer 210 can have a monolayer structure by the refractive index particles 212. In more detail, the refractive index particles 212 can form a monolayer structure in the refractive index particle layer 210. The expression that the refractive index particles 212 form a monolayer means that the refractive index particles 212 are not stacked each other, but arranged to form a single layer.

When the refractive index particle layer 210 has a monolayer structure by the refractive index particles 212, an optical path difference can be created by varying the optical path (OPL) of external light and reflected light without lowering the transmittance due to diffuse reflection.

FIG. 11B is a schematic diagram illustrating a structure in which particles are dispersed and stacked in a matrix. In FIG. 11B, the particles do not form a monolayer structure.

Referring to FIG. 11B, the particles dispersed and stacked within the matrix change the direction of light travel in multiple directions, causing diffuse reflection of light (see right side of FIG. 11B). This diffuse reflection can cause back scattering, and the light emitted from the organic light emitting element 160 can also be diffusely reflected and scattered, resulting in reduced transmittance.

Unlike the structure of FIG. 11B, the coherence prevention layer 200 according to an embodiment of the present disclosure can have a monolayer structure of refractive index particles 212, which can prevent or suppress coherence of reflected light by generating an optical path difference without reducing transmittance due to diffuse reflection.

According to an embodiment of the present disclosure, the refractive index particle layer 210 has a packing density of 90% or more in a plan view. According to an embodiment of the present disclosure, the packing density is calculated as the ratio of the area of the refractive index particles 212 to the area of the refractive index particle layer 210 in a plan view. In more detail, packing density indicates how densely the refractive index particles 212 are arranged in a plan view.

According to an embodiment of the present disclosure, since the refractive index particle layer 210 has a packing density of 90% or more in a plan view, almost all light passing through the coherence prevention layer 200 passes through the refractive index particles 212. As a result, the proportion of light that is diffusely reflected without passing through the refractive index particles 212 can be minimized, and a decrease in transmittance due to diffuse reflection can be prevented or suppressed.

If the packing density of the refractive index particle layer 210 is less than 90%, diffuse reflection can occur due to light that does not pass through the refractive index particles 212 of the coherence prevention layer 200, and coherence can also occur, resultingly a reflection diffraction mura pattern can be formed due to the reflection of external light.

In more detail, light that does not pass through the refractive index particles 212 of the coherence prevention layer 200 can cause a reflection diffraction mura pattern. However, according to an embodiment of the present disclosure, as the index particle layer 210 is designed to have a packing density of 90% or more in a plan view, almost all light incident from the outside passes through the refractive index particles 212 of the refractive index particle layer 210, and thus a decrease in transmittance due to diffuse reflection can be effectively prevented.

According to an embodiment of the present disclosure, the coherence prevention layer 200 is disposed on the color filter layer 150.

According to an embodiment of the present disclosure, the coherence prevention layer 200 can be formed directly on the display panel 310, or the coherence prevention layer 200 can be manufactured separately from the display panel 310, and then attached to the display panel 310.

When the coherence prevention layer 200 is attached to the display panel 310, an adhesive layer or bonding layer can be disposed between the coherence prevention layer 200 and the display panel 310.

According to an embodiment of the present disclosure, the display apparatus 1100 does not include a polarizer. The display apparatus 1100 according to an embodiment of the present disclosure uses a coherence prevention layer 200 instead of a polarizer to suppress or prevent the generation of a diffraction interference pattern due to reflection of external light.

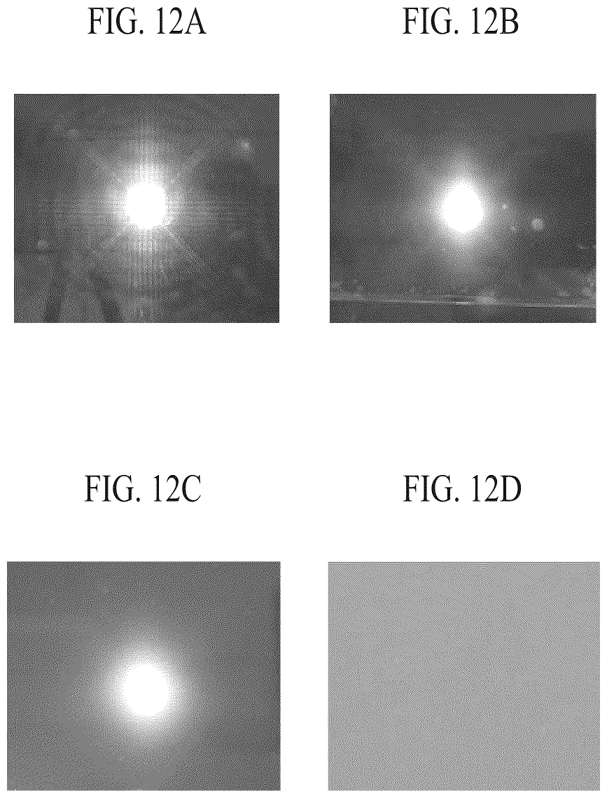

FIGS. 12A and 12B are pictures diffraction patterns caused by an external light on display apparatuses according to comparative examples. FIGS. 12C and 12D are pictures of display apparatuses illuminated by an external light source, according to an embodiment of the present disclosure.

Particularly, FIG. 12A is a picture of reflected light after a point light source, as an external light, is irradiated on a display apparatus according to a comparative example, having an optical layer disposed thereon. The optical layer has the same laminated structure as the above-described coherence prevention layer 200, but is designed so that the refractive index particles 212 and the filling layer 220 do not have a difference in refractive index. In detail, in the display apparatus of FIG. 12A, an optical layer, in which a refractive index of the refractive index particles 212 is 1.49, a refractive index of the light-transmissive matrix 211 is 1.47, and a refractive index of the filling layer 220 is 1.49, is disposed on a display panel. PMMA-based beads were used as refractive index particles 212.

Referring to FIG. 12A, it can be seen that when there is no difference between the refractive index of the refractive index particles 212 and the refractive index of the filling layer 220, a diffraction interference pattern is generated. As shown in FIG. 12A, diffraction interference patterns are not prevented or suppressed in the display apparatus according to the comparative example.

FIG. 12B is a picture of reflected light after a point light source, as an external light, is irradiated on a display apparatus according to a comparative example, having an optical layer disposed thereon. The optical layer is designed such that the difference in refractive index between the refractive index particles 212 and the filling layer 220 is 0.03. In detail, in the display apparatus of FIG. 12B, an optical layer, in which a refractive index of the refractive index particles 212 is 1.49, a refractive index of the light-transmissive matrix 211 is 1.47, and a refractive index of the filling layer 220 is 1.52, is disposed on a display panel. PMMA-based beads were used as refractive index particles 212.

Referring to FIG. 12B, when the difference between the refractive index of the refractive index particle 212 and the refractive index of the filling layer 220 is 0.03, it can be shown that although the diffraction interference pattern is reduced compared to FIG. 12A, the diffraction interference pattern is still generated.

On the other hand, FIG. 12C is a picture of reflected light after a point light source, as an external light, is irradiated on a display apparatus according to an embodiment, having a coherence prevention layer 200 disposed thereon. The coherence prevention layer 200 is designed such that the difference in refractive index between the refractive index particles 212 and the filling layer 220 is 0.05. In detail, in the display apparatus of FIG. 12C, a coherence prevention layer 200, in which a refractive index of the refractive index particles 212 is 1.49, a refractive index of the light-transmissive matrix 211 is 1.47, and a refractive index of the filling layer 220 is 1.54, is disposed on the display panel 310. PMMA beads were used as refractive index particles 212.

Referring to FIG. 12C, it can be shown that when the difference between the refractive index of the refractive index particles 212 and the refractive index of the filling layer 220 is 0.05, the diffraction interference pattern is significantly reduced.

FIG. 12D is a picture of reflected light after a point light source, as an external light, is irradiated on a display apparatus according to an embodiment, having a coherence prevention layer 200 disposed thereon. The coherence prevention layer 200 is designed such that the difference in refractive index between the refractive index particles 212 and the filling layer 220 is 0.4. In detail, in the display apparatus of FIG. 12D, a coherence prevention layer 200, in which a refractive index of the refractive index particles 212 is 1.49, a refractive index of the light-transmissive matrix 211 is 1.47, and a refractive index of the filling layer 220 is 1.89, is disposed on the display panel 310. PMMA beads were used as refractive index particles 212.

Referring to FIG. 12D, it can be shown that when the difference between the refractive index of the refractive index particles 212 and the refractive index of the filling layer 220 is 0.4, no detectible diffraction interference pattern was generated. In addition, it can be shown that the point light source used as external light is not recognized due to the increased turbidity.

In addition, referring to FIG. 12D, it can be shown that when the difference between the refractive index of the refractive index particles 212 and the refractive index of the filling layer 220 exceeds 0.4, turbidity further increases, which deteriorates the black image quality of the display apparatus.

Thus, according to an embodiment of the present disclosure, the difference between the refractive index of the refractive index particles 212 and the refractive index of the filling layer 220 is adjusted to a range of 0.05 to 0.4.

Another embodiment of the present disclosure provides a coherence prevention member 1200.

FIG. 13 is a schematic cross-sectional view of a coherence prevention member 1200 according to another embodiment of the present disclosure.

The coherence prevention member 1200 according to another embodiment of the present disclosure can have substantially the same structure as the coherence prevention layer 200 described above. Hereinafter, to avoid redundancy, descriptions of already described components are omitted.

Referring to FIG. 13, the coherence prevention member 1200 can have a film or sheet shape. Accordingly, the coherence prevention member 1200 can be referred to as a coherence prevention film or a coherence prevention sheet.

The coherence prevention member 1200 according to another embodiment of the present disclosure includes a refractive index particle layer 210 and a filling layer 220 on the refractive index particle layer 210. The refractive index particle layer 210 includes a light-transmissive matrix 211 and refractive index particles 212 dispersed in the light-transmissive matrix 211.

The refractive index particles 212 can include a first particles 212a and a second particles 212b. The first particle 212a can have a first refractive index, and the second particle 212b can have a second refractive index. According to an embodiment of the present disclosure, the first refractive index and the second refractive index can be different from each other.

The first particles 212a and the second particles 212b can have the same particle size or different particle sizes. Referring to FIG. 13, the first particles 212a and the second particles 212b can have different particle sizes. According to an embodiment of the present disclosure, the diameter of the particle is referred to as the particle size. The particle diameter of a particle can also be referred to as the particle size.

The refractive index particles 212 can have an average particle diameter of 760 nm to 20 μm.

The light-transmissive matrix 211, the refractive index particles 212, and the filling layer 220 can have different refractive indices.

The refractive index difference between the refractive index particles 212 and the filling layer 220 can be designed to range from 0.05 to 0.40.

The first particles 212a and the second particles 212b can have different refractive indices. For example, the first particle 212a and the second particle 212b can have a difference in refractive index ranging from 0.05 to 0.40.

The refractive index particles 212 can further include a third particle 212c having a different refractive index from the first particles 212a and the second particles 212b. The third particle 212c can have the same particle size as the first particle 212a and the second particle 212b, or can have a different particle size.

The refractive index particles 212 can be made of a material having light transparency. The refractive index particles 212 can include, for example, at least one of polymethyl methacrylate (PMMA), polycarbonate (PC), polyethylene terephthalate (PET), polyurethane (PU), polystyrene (PS), nylon, silicone oxide (SiO2), titanium oxide (TiO2), silicon nitride (SixNy), silicon oxynitride (SiON), aluminum oxide (AlOx), aluminum nitride (AlON), zinc oxide (ZnO), tantalum oxide (Ta2O5), magnesium fluoride (MgF2), yttrium oxide (Y2O3), and hafnium oxide (HfO2).

According to another embodiment of the present disclosure, the refractive index particles 212 can be made of a light-transmissive organic material. The refractive index particles 212 can include, for example, at least one of polymethyl methacrylate (PMMA), polycarbonate (PC), polyethylene terephthalate (PET), polyurethane (PU), polystyrene (PS), and nylon.

The first particles 212a, second particles 212b, and third particles 212c can be made of the same material or can be made of different materials.

The refractive index particle layer 210 can have a plurality of lens patterns (see FIG. 11A). In more detail, the refractive index particle layer 210 can have a plurality of lens patterns resulting from the shape of the refractive index particles 212.

The refractive index particle layer 210 can have a monolayer structure formed by the refractive index particles 212. In more detail, the refractive index particles 212 can be arranged as a single layer in the refractive index particle layer 210.

The refractive index particle layer 210 has a packing density of 90% or more in a plan view. According to another embodiment of the present disclosure, the packing density is calculated as the ratio of the area of the refractive index particles 212 to the area of the refractive index particle layer 210 in a plan view.

Another embodiment of the present disclosure provides a display apparatus 1300 including a coherence prevention member 1200.

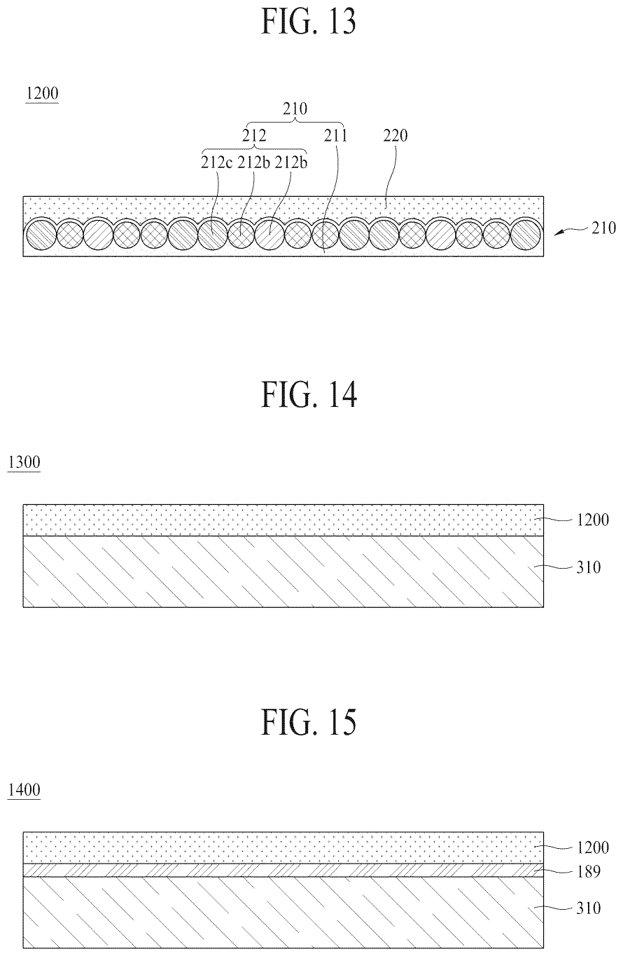

FIG. 14 is a schematic cross-sectional view of a display apparatus 1300 according to another embodiment of the present disclosure.

Referring to FIG. 14, the coherence prevention member 1200 can be disposed on the display panel 310.

In more detail, the display apparatus 1300 according to another embodiment of the present disclosure includes a color filter layer 150, and the coherence prevention member 1200 can be disposed on the color filter layer 150.

FIG. 15 is a schematic cross-sectional view of a display apparatus 1400 according to another embodiment of the present disclosure.

Referring to FIG. 15, the coherence prevention member 1200 can be attached to the display panel 310. In order to attach the coherence prevention member 1200 to the display panel 310, an adhesive layer 189 can be provided between the coherence prevention member 1200 and the display panel 310. The adhesive layer 189 can have light transparency.

As such, a display apparatus and a coherence prevention member according to various aspects of the present disclosure provide advantages and features, which allow them to minimize the occurrence of spectral dispersion patterns that can be caused by destructive interference or constructive interference of reflected light when an external light is reflected.

The present disclosure described above is not limited to the above-described embodiments and the accompanying drawings. The fact that various substitutions, modifications, and changes are possible within the scope of the technical details of the present disclosure is obvious to anyone with ordinary skill in the art.

What is claimed is:

1. A display apparatus comprising:
a display panel configured to display an image; and
a coherence prevention layer on the display panel,
wherein the coherence prevention layer comprises:
a refractive index particle layer; and
a filling layer on the refractive index particle layer,
wherein the refractive index particle layer comprises:
a light-transmissive matrix; and
refractive index particles dispersed in the light-transmissive matrix, and
wherein the filling layer and the refractive index particles have different refractive indices.

2. The display apparatus of claim 1, wherein the refractive index particles include a first particle and a second particle,
wherein the first particle has a first refractive index and the second particle has a second refractive index, and
wherein the first refractive index is different from the second refractive index.

3. The display apparatus of claim 1, wherein a difference between the refractive index of the refractive index particles and the refractive index of the filling layer is in a range of about 0.05 to about 0.40.

4. The display apparatus of claim 2, wherein the first particle and the second particle have a refractive index difference in a range of about 0.05 to about 0.40.

5. The display apparatus of claim 2, wherein the first particle and the second particle have different particle diameters.

6. The display apparatus of claim 1, wherein the refractive index particles have an average particle diameter of about 760 nm to about 20 μm.

7. The display apparatus of claim 2, wherein the refractive index particles further comprise a third particle having a refractive index different from the first refractive index of the first particle and the second refractive index of the second particle.

8. The display apparatus of claim 1, wherein the refractive index particles comprise at least one selected from the group consisting of polymethylmethacrylate (PMMA), polycarbonate (PC), polyethylene terephthalate (PET), polyurethane (PU), polystyrene (PS), nylon, silicon oxide (SiO2), titanium oxide (TiO2), silicon nitride (SixNy), silicon oxide nitride (SiON), aluminum oxide (AlOx), aluminum nitride (AlON), zinc oxide (ZnO), tantalum oxide (Ta2O5), magnesium fluoride (MgF2), yttrium oxide (Y2O3), and hafnium oxide (HfO2).

9. The display apparatus of claim 1, wherein the refractive index particle layer has a plurality of lens patterns.

10. The display apparatus of claim 1, wherein the refractive index particle layer has a monolayer structure by the refractive index particles.

11. The display apparatus of claim 10, wherein the refractive index particle layer has a packing density of 90% or more in a plan view, and
wherein the packing density is calculated as a ratio of an area of the refractive index particles to an area of the refractive index particle layer, in a plan view.

12. The display apparatus of claim 1, wherein the display panel comprises a color filter layer, and
wherein the coherence prevention layer is disposed on the color filter layer.

13. A coherence prevention member comprising:
a refractive index particle layer; and
a filling layer on the refractive index particle layer,
wherein the refractive index particle layer comprises:
a light-transmissive matrix; and
refractive index particles dispersed in the light-transmissive matrix, and
wherein the refractive index particles and the filling layer have different refractive indices.

14. The coherence prevention member of claim 13, wherein the refractive index particles include a first particle and a second particle,
wherein the first particle has a first refractive index and the second particle has a second refractive index, and
wherein the first refractive index is different from the second refractive index.

15. The coherence prevention member of claim 14, wherein the first particle and the second particle have different particle diameters.

16. The coherence prevention member of claim 13, wherein the refractive index particles have an average particle diameter of about 760 nm to about 20 μm.

17. The coherence prevention member of claim 13, wherein a difference in refractive index between the refractive index particles and the filling layer is in a range of about 0.05 to about 0.40.

18. The coherence prevention member of claim 14, wherein the first particle and the second particle have a refractive index difference in the range of about 0.05 to about 0.40.

19. The coherence prevention member of claim 14, wherein the refractive index particles further comprise a third particle having a refractive index different from the first refractive index of the first particle and the second refractive index of the second particle.

20. The coherence prevention member of claim 13, wherein the refractive index particles comprise at least one selected from the group consisting of polymethylmethacrylate (PMMA), polycarbonate (PC), polyethylene terephthalate (PET), polyurethane (PU), polystyrene (PS), nylon, silicon oxide (SiO2), titanium oxide (TiO2), silicon nitride (SixNy), silicon oxide nitride (SiON), aluminum oxide (AlOx), aluminum nitride (AlON), zinc oxide (ZnO), tantalum oxide (Ta2O5), magnesium fluoride (MgF2), yttrium oxide (Y2O3), and hafnium oxide (HfO2).

21. The coherence prevention member of claim 13, wherein the refractive index particle layer has a plurality of lens patterns.

22. The coherence prevention member of claim 13, wherein the refractive index particle layer has a monolayer structure by the refractive index particles.

23. The coherence prevention member of claim 22, wherein the refractive index particle layer has a packing density of 90% or more in a plan view, and
wherein the packing density is calculated as a ratio of an area of the refractive index particles to an area of the refractive index particle layer, in a plan view.

24. A display apparatus comprising:
a display panel; and
the coherence prevention member of claim 13, disposed on the display panel.

25. The display apparatus of claim 24, wherein the display apparatus excludes a polarizer.
